(19) United States
(12) Patent Application Publication
(10) Pub. No.: US 2011/0171365 A1
(43) Pub. Date: Jul. 14, 2011

(54) METHOD FOR MODIFYING A TRANSPARENT ELECTRODE FILM

(75) Inventor: Toshiya Kuroda, Ibaraki (JP)

(73) Assignee: SUMITOMO CHEMICAL COMPANY, LIMITED, Chuo-ku, Tokyo (JP)

(21) Appl. No.: 13/063,483

(22) PCT Filed: Sep. 11, 2009
(86) PCT No.: PCT/JP2009/066324

§ 371 Date: Mar. 11, 2011

(30) Foreign Application Priority Data
Sep. 12, 2008 (JP) 2008-234731

(51) Int. Cl. B29C 59/16; B05D 5/12

(52) U.S. Cl. 427/78; 264/447

(57) ABSTRACT

A method for modifying a transparent electrode film contained in a transparent electrode film-attached substrate having a substrate and the transparent electrode film formed on the substrate includes annealing the transparent electrode film by applying flash light having an optical pulse duration time of 0.1 msec to 10 msec to the transparent electrode film using a flash lamp, thereby heating the transparent electrode film.

### TECHNICAL FIELD

The present invention relates to a method for modifying a transparent electrode film contained in a transparent electrode film-attached substrate for use in a light emitting device and the like, thereby reducing the resistivity of the film, and a method for manufacturing a transparent electrode film-attached substrate using that method.

### BACKGROUND ART

In a light emitting device such as an organic electroluminescent device (organic EL device), a transparent electrode film is generally used as an electrode located on a light extraction side to extract light emitted from a light emitting layer. Further, in order to increase the amount of the light emitted from the light emitting layer, the lower the resistivity of the transparent electrode film is, the more preferred. Therefore, a technique to form a transparent electrode film having a lower resistivity and a technique to reduce the resistivity of a transparent electrode film after forming the transparent electrode film are under study. As an example of such a method to reduce the resistivity of a transparent electrode film, for example, JP 2000-282225 A (Patent Document 1) discloses a method comprising forming an indium tin oxide (ITO) film made of ITO as a transparent electrode material and then annealing the film at 180° C. or higher in a furnace to reduce the resistivity of the ITO film.

The conventional method as described in Patent Document 1, however, has required a long time for annealing, and has not necessarily been sufficient in terms of production efficiency. Further, there has been such a problem that when the material of the substrate is an organic material such as a resin, the substrate is distorted or the resin is changed in properties to deteriorate due to the heat of the furnace during the annealing.

### DISCLOSURE OF INVENTION

The present invention was devised in view of the problems associated with the conventional techniques. It is an object of the present invention to provide a method for modifying a transparent electrode film contained in a transparent electrode film-attached substrate comprising a substrate and the transparent electrode film formed on the substrate, by which method the resistivity of the transparent electrode film can be reduced efficiently in a short time, while inhibiting thermal deterioration and thermal distortion of the substrate, and also provide a method for manufacturing a transparent electrode film-attached substrate using that method.

The method of the present invention for modifying a transparent electrode film comprises annealing the transparent electrode film by applying flash light having an optical pulse duration time of 0.1 msec to 10 msec to the transparent electrode film using a flash lamp, thereby heating the transparent electrode film.

Additionally, in the method of the present invention for modifying a transparent electrode film, the transparent electrode film is preferably one having been formed on the substrate by at least one film-forming method selected from the group consisting of a vacuum evaporation method, a sputtering method, an ion-plating method, an ion-beam method, an atmospheric pressure chemical vapor deposition method, a low pressure chemical vapor deposition method, a plasma chemical vapor deposition method, a photochemical vapor deposition method, and a plasma polymerization method.

The method of the present invention for manufacturing a transparent electrode film-attached substrate comprises the steps of:

forming a transparent electrode film on a substrate by at least one film-forming method selected from the group consisting of a vacuum evaporation method, a sputtering method, an ion-plating method, an ion-beam method, an atmospheric pressure chemical vapor deposition method, a low pressure chemical vapor deposition method, a plasma chemical vapor deposition method, a photochemical vapor deposition method, and a plasma polymerization method; and

annealing the transparent electrode film by applying flash light having an optical pulse duration time of 0.1 msec to 10 msec to the transparent electrode film using a flash lamp, thereby heating the transparent electrode film.

In the method of the present invention for modifying a transparent electrode film and the method of the present invention for manufacturing a transparent electrode film-attached substrate, a light irradiation dose in the annealing is preferably 2 J/cm² to 50 J/cm².

In the method of the present invention for modifying a transparent electrode film and the method for manufacturing a transparent electrode film-attached substrate of the present invention, the transparent electrode film is preferably made of at least one transparent electrode material selected from the group consisting of indium tin oxide and zinc oxide.

The method of the present invention for modifying a transparent electrode film can efficiently reduce the resistivity of a transparent electrode film and also inhibit thermal deterioration and thermal distortion of a substrate in a method for modifying a transparent electrode film contained in a transparent electrode film-attached substrate comprising the substrate and the transparent electrode film formed on the substrate. Specifically, in the present invention, a transparent electrode film is annealed by applying flash light having an optical pulse duration time of 0.1 msec to 10 msec using a flash lamp, thereby heating the transparent electrode film, and in the annealing by means of such a flash lamp, energy can be intensively supplied to the neighborhood of a surface on which the flash light is applied. Thus, the transparent electrode film can be intensively supplied with energy, which makes the transparent electrode film to be efficiently annealed. In other words, as compared with the conventional annealing in the furnace, energy can be more efficiently supplied to the transparent electrode film in a short time, and the resistivity of the transparent electrode film can be more efficiently reduced. Additionally, in the annealing by such a flash lamp, since excess energy may be prevented from being supplied to the substrate other than the neighborhood of the surface on which flash light is applied, thermal deterioration and thermal distortion of the substrate can be inhibited.

The present invention can provide a method for modifying a transparent electrode film contained in a transparent electrode film-attached substrate comprising a substrate and the transparent electrode film formed on the substrate, by which method the resistivity of the transparent electrode film can be reduced efficiently in a short time, while inhibiting thermal deterioration and thermal distortion of the substrate. In addition, the invention can also provide a method for manufacturing a substrate with a transparent electrode film using that method.

### BRIEF DESCRIPTION OF DRAWINGS

FIG. 1 is an emission spectrum showing the relationship between a wavelength and emission output in a flash lamp used in Examples.

### BEST MODE(S) FOR CARRYING OUT THE INVENTION

Hereinafter, the present invention will be described in detail along with a preferred embodiment of the present invention.

The method of the present invention for modifying a transparent electrode film is a method for modifying a transparent electrode film contained in a transparent electrode film-attached substrate comprising a substrate and the transparent electrode film formed on the substrate. The method is characterized by annealing the transparent electrode film by applying flash light having an optical pulse duration time of 0.1 msec to 10 msec to the transparent electrode film using a flash lamp, thereby heating the transparent electrode film.

In addition, the method of the present invention for manufacturing a transparent electrode film-attached substrate comprises the steps of:

forming a transparent electrode film on a substrate by at least one film-forming method selected from the group consisting of a vacuum evaporation method, a sputtering method, an ion-plating method, an ion-beam method, an atmospheric pressure chemical vapor deposition method, a low pressure chemical vapor deposition method, a plasma chemical vapor deposition method, a photochemical vapor deposition method, and a plasma polymerization method; and

annealing the transparent electrode film by applying flash light having an optical pulse duration time of 0.1 msec to 10 msec to the film using a flash lamp, thereby heating the film.

The substrate to be used in the present invention is an item that serves as a support substrate for forming a transparent electrode film in a light emitting device and the like. The material of such a substrate is properly selected depending on applications of the transparent electrode film-attached substrate to be obtained and therefore it is not particularly limited. When the obtained transparent electrode film-attached substrate is used in a light emitting device or the like, examples thereof include glass, silicon, thermosetting resin, and thermoplastic resin. In the present invention, since thermal deterioration and thermal distortion of a substrate can be inhibited, a resin (an organic material) such as a thermosetting resin and a thermoplastic resin, which is lower in heat resistance than inorganic materials such as glass, can be suitably used as the material of the substrate.

The thickness of the substrate is properly selected depending on applications of the transparent electrode film-attached substrate to be obtained, and therefore it is not particularly limited. When the substrate with a transparent electrode film attached thereto is used in a light emitting device and the like, the thickness of the substrate is generally within a range of 50 μm to 5 mm, and preferably 100 μm to 2 mm.

The transparent electrode film according to the present invention is a transparent electrode film used as an electrode located on a light extraction side in a light emitting device and the like. As a material constituting such a transparent electrode film, a transparent electrode material having high electrical conductivity and light transmission is used. For example, indium oxide, zinc oxide, tin oxide, indium tin oxide (ITO), indium zinc oxide, tin oxide doped with fluorine or antimony, zinc oxide doped with aluminium or gallium, gold, platinum, silver, and copper are used. Among them, ITO and zinc oxide are preferred from the viewpoint of electrical conductivity and light transmission.

The thickness of the transparent electrode film is properly selected depending on applications of the transparent electrode film-attached substrate to be obtained, and therefore it is not particularly limited. When the substrate with a transparent electrode film attached thereto is used in a light emitting device and the like, the thickness of the film is preferably 20 nm to 1 μm, and more preferably 50 nm to 500 nm.

The surface resistivity of the transparent electrode film is preferably 100 Ω/square or less, and more preferably 50 Ω/square or less. When the surface resistivity of the transparent electrode film is high, the film is less prone to have a resistivity low enough for a transparent electrode film to be used in a light emitting device and the like even if the film is modified by annealing as described below. The surface resistivity can be measured by a method in accordance with the testing method for resistivity with a four-point probe array disclosed in JIS K7194.

The transparent electrode film-attached substrate according to the present invention comprises the substrate and the transparent electrode film formed on the substrate. The transparent electrode film-attached substrate can be obtained by forming the transparent electrode film on the substrate. As such a film-forming method for forming a transparent electrode film on a substrate, a film-forming method by which a transparent electrode film having a surface resistivity equal to or less than the upper limit can be formed is preferably employed. As the film-forming method for forming a transparent electrode film on a substrate, such methods as a vacuum evaporation method, a sputtering method, an ion-plating method, an ion-beam method, an atmospheric pressure chemical vapor deposition method (atmospheric pressure CVD), a low pressure chemical vapor deposition method (low pressure CVD), a plasma chemical vapor deposition method (plasma CVD), a photochemical vapor deposition method (photo-CVD), a plasma polymerization method, a sol-gel, coating pyrolysis method, and a fine particle dispersion method are generally employed. In the present invention, at least one film-forming method selected from the group consisting of physical vapor deposition methods (PVD) such as a vacuum evaporation method, a sputtering method, an ion-plating method, and an ion-beam method; and chemical vapor deposition methods (CVD) such as an atmospheric pressure chemical vapor deposition method, a low pressure chemical vapor deposition method, a plasma chemical vapor deposition method, a photochemical vapor deposition method, and a plasma polymerization method is preferably employed from the viewpoint of surface resistivity of the transparent electrode film to be obtained. A sputtering method or an ion-plating method is more preferably employed.

In the present invention, the transparent electrode film is annealed by heating the film by applying flash light having an optical pulse duration time of 0.1 msec to 10 msec to the film using a flash lamp. As the flash lamp to be used for the annealing can be selected appropriately and used a lamp which emits flash light having a wavelength partially overlapping the absorption wavelength of a transparent electrode material. For example, when ITO is used as the transparent electrode material, it is necessary to use a lamp which emits flash light having a wavelength region of 300 nm to 400 nm, which corresponds to the absorption wavelength of ITO. Examples of such a flash lamp include a xenon lamp. Although the atmosphere under which the annealing is performed is not particularly limited, an atmosphere of inert gas such as argon and nitrogen is preferred.

The optical pulse duration time of the flash light in the annealing is 0.1 msec to 10 msec, and preferably 0.1 msec to 1.0 msec. When the optical pulse duration time is short, it becomes difficult to control the optical pulse duration time itself, easily resulting in an inconvenience, such as the occurrence of variation in optical pulse duration time between runs of annealing such that the resistivity may decrease. On the other hand, when it is long, excess energy is supplied by flash light to a substrate part other than a transparent electrode film, and therefore thermal deterioration and thermal distortion of the substrate cannot be inhibited sufficiently. The light irradiation dose of flash light in the annealing is 2 J/cm² to 50 J/cm², and preferably 2 J/cm² to 30 J/cm². When the light irradiation dose falls within the above range, thermal deterioration and thermal distortion of the substrate can be inhibited sufficiently while sufficiently reducing the resistivity of the transparent electrode film. Further, it is preferable that the light irradiation dose be properly optimized depending on the optical pulse duration time, types of flash annealing device, or the like. The light irradiation dose of flash light used herein refers to the value of input energy of a flash lamp (unit: J) divided by the area of the region irradiated with the flash lamp (unit: cm²).

During the annealing, the transparent electrode film is usually heated to 150° C. to 600° C. In the annealing, from the viewpoint of modifying a transparent electrode film while suppressing thermal deterioration and thermal distortion of the substrate, the optical pulse duration time and the light irradiation dose are preferably adjusted so that the temperature of the transparent electrode film may be 200° C. to 300° C.

The surface resistivity of the modified transparent electrode film having been thus annealed is preferably 30 Ω/square or less, and more preferably 10 Ω/square or less. When the modified transparent electrode film has such a low surface resistivity, it can be suitably used as a transparent electrode film for use in a light emitting device and the like. In the present invention, the surface resistivity of the modified transparent electrode film is preferably equal to or less than a half of the surface resistivity of the transparent electrode film before modification.

According to the method of the present invention for modifying a transparent electrode film and the method of the present invention for manufacturing a transparent electrode film attached-substrate described above, the resistivity of a transparent electrode film can be reduced efficiently in a short time while inhibiting the thermal deterioration and the thermal distortion of the substrate. Since the method of the present invention for modifying a transparent electrode film can modify the transparent electrode film while inhibiting the thermal deterioration and the thermal distortion of the substrate, the method is one particularly suitable as a method for modifying a transparent electrode film attached-substrate comprising a substrate made of a resin (an organic material) such as a thermosetting resin and a thermoplastic resin, which is lower in heat resistance than inorganic materials such as glass. Further, the transparent electrode film attached-substrate obtained by the method of the present invention for modifying a transparent electrode film and the method of the present invention for manufacturing a transparent electrode film-attached substrate is provided with a transparent electrode film having a low resistivity; therefore, it can be used particularly suitably as a transparent electrode film-attached substrate for use in an organic electroluminescent device (organic EL device) which comprises a substrate, a barrier layer, a first electrode made of a transparent electrode material, a second electrode opposite to the first electrode, and at least one light emitting layer interposed between the first and second electrodes.

### EXAMPLES

Hereinafter, the present invention will be further specifically described on the basis of Examples and Comparative Examples. However, the present invention is not limited to the following Examples. The surface resistivity of a transparent electrode film was determined by the following method.

(i) Surface Resistivity

The surface resistivity (unit: Ω/square) of a transparent electrode film was determined with a surface resistivity meter (manufactured by Mitsubishi Chemical Corporation, trade name “Lresta GP MCP-T610”) in accordance with the testing method for resistivity with a four-point probe array disclosed in JIS K7194.

### Example 1

A substrate (material: glass, thickness: 0.7 mm) was introduced into a sputtering apparatus (manufactured by FTS Corporation, trade name “FTS (facing target sputtering) equipment”). A transparent electrode film (material: ITO, thickness: 150 nm) was formed on the surface of the substrate by a sputtering method under the following conditions, so that a transparent electrode film-attached substrate was obtained. The surface resistivity of the transparent electrode film in the obtained transparent electrode film-attached substrate was 51.7 Ω/square.

Film-forming pressure: 0.5 Pa
Ar flow rate: 40 scc/m
Oxygen flow rate: 0.5 scc/m
Input power: DC 1 kW
Film-forming rate: 11 nm/m
Target: ITO (10% by mass SnO₂)

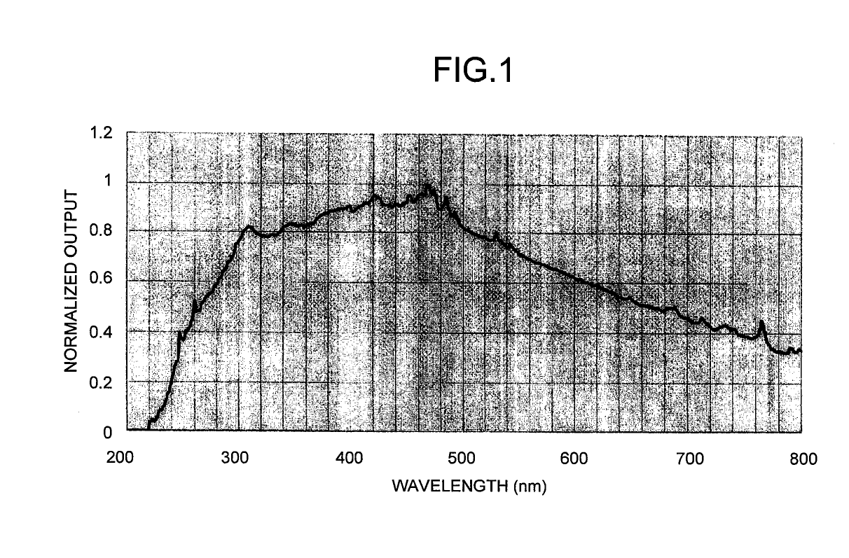

Flash light was then applied to the surface of the transparent electrode film of the obtained transparent electrode film-attached substrate using a flash annealing apparatus manufactured by USHIO INC. The transparent electrode film was annealed by a flash lamp, so that a transparent electrode film-attached substrate that had been modified was obtained. The optical pulse duration time of flash light in the annealing was 0.2 msec. The light irradiation dose of flash light used in the annealing was 5 J/cm². The emission spectrum of the flash lamp used in the annealing is shown in FIG. 1.

When measured, the surface resistivity of the transparent electrode film in the modified substrate with a transparent electrode film was 18.4 Ω/square. Therefore, according to the method of the present invention for modifying a transparent electrode film, it was confirmed that short-time annealing could sufficiently reduce the surface resistivity of the transparent electrode film.

### Comparative Example 1

A substrate with a modified transparent electrode film was obtained in the same manner as in Example 1, except that a transparent electrode film-attached substrate was annealed in a furnace at a heating temperature of 230° C. for one hour using a clean oven manufactured by Yamato Scientific. Co., Ltd. The surface resistivity of the modified transparent electrode film in the transparent electrode film-attached substrate was 15.0 Ω/square. The annealing was able to reduce the surface resistivity of the transparent electrode film sufficiently. However, the treatment time for annealing was as long as one hour.

### Comparative Example 2

A substrate with a modified transparent electrode film was obtained in the same manner as in Example 1, except that a transparent electrode film-attached substrate was annealed in a furnace at a heating temperature of 230° C. for 20 minutes using a clean oven manufactured by Yamato Scientific. Co., Ltd. The surface resistivity of the modified transparent electrode film in the transparent electrode film-attached substrate was 28.8 Ω/square. The annealing was not able to reduce the surface resistivity of the transparent electrode film sufficiently.

### Example 2

A transparent electrode film-attached substrate and a transparent electrode film-attached substrate that had been modified were obtained in the same manner as in Example 1, except that instead of that substrate (material: glass, thickness: 0.7 mm) a substrate made of a resin (material: polyethylene naphthalate, thickness: 125 μm) was used. The surface resistivity of the transparent electrode film in the transparent electrode film-attached substrate before modification was 53.2 Ω/square. The surface resistivity of the modified transparent electrode film in the transparent electrode film-attached substrate that had been modified was 18.4 Ω/square. The substrate made of a resin was not changed in shape and color. Therefore, according to the method of the present invention for modifying a transparent electrode film, it was confirmed that short-time annealing could sufficiently reduce the surface resistivity of a transparent electrode film. In addition, it was confirmed that the method of the present invention for modifying a transparent electrode film of the present invention could be used for the transparent electrode film-attached substrate having a substrate made of a resin being lower in heat resistance than glass.

### Comparative Example 3

A substrate with a modified transparent electrode film was obtained in the same manner as in Example 2, except that a transparent electrode film-attached substrate was annealed in a furnace at a heating temperature of 230° C. for one hour using a clean oven manufactured by Yamato Scientific. Co., Ltd. The surface resistivity of the modified transparent electrode film in the transparent electrode film-attached substrate was 15.0 Ω/square. The annealing could sufficiently reduce the surface resistivity of the transparent electrode film. However, when the appearance of the transparent electrode film-attached substrate that had been modified was visually observed, it was confirmed that the substrate made of a resin had been changed in shape and color by heat.

### INDUSTRIAL APPLICABILITY

As described above, the present invention can provide the method for modifying a transparent electrode film in a transparent electrode film-attached substrate which comprises a substrate and the transparent electrode film formed on the substrate, wherein the resistivity of the transparent electrode film can be efficiently reduced in a short time, while suppressing the thermal deterioration and the thermal distortion of the substrate. In addition, the invention can also provide a method for manufacturing a transparent electrode film-attached substrate by that method.

Accordingly, the method of the present invention for modifying a transparent electrode film is useful as a method for modifying a transparent electrode film in a transparent electrode film-attached substrate for use in a light emitting device and the like, thereby reducing the resistivity of the film.

1. A method for modifying a transparent electrode film contained in a transparent electrode film-attached substrate comprising a substrate and the transparent electrode film formed on the substrate, the method comprising:
annealing the transparent electrode film by applying flash light having an optical pulse duration time of 0.1 msec to 10 msec to the transparent electrode film using a flash lamp, thereby heating the transparent electrode film.

2. The method according to claim 1, wherein a light irradiation dose in the annealing is 2 J/cm² to 50 J/cm².

3. The method according to claim 1, wherein the transparent electrode film is made of at least one transparent electrode material selected from the group consisting of indium tin oxide and zinc oxide.

4. The method according to claim 1, wherein the transparent electrode film is formed on the substrate by at least one film-forming method selected from the group consisting of a vacuum evaporation method, a sputtering method, an ion-plating method, an ion-beam method, an atmospheric pressure chemical vapor deposition method, a low pressure chemical vapor deposition method, a plasma chemical vapor deposition method, a photochemical vapor deposition method, and a plasma polymerization method.

5. A method for manufacturing a transparent electrode film-attached substrate, the method comprising the steps of:
forming a transparent electrode film on a substrate by at least one film-forming method selected from the group consisting of a vacuum evaporation method, a sputtering method, an ion-plating method, an ion-beam method, an atmospheric pressure chemical vapor deposition method, a low pressure chemical vapor deposition method, a plasma chemical vapor deposition method, a photochemical vapor deposition method, and a plasma polymerization method; and
annealing the transparent electrode film by applying flash light having an optical pulse duration time of 0.1 msec to 10 msec to the transparent electrode film using a flash lamp, thereby heating the transparent electrode film.

6. The manufacturing method according to claim 5, wherein a light irradiation dose in the annealing is 2 J/cm² to 50 J/cm².

7. The manufacturing method according to claim 5, wherein the transparent electrode film is made of at least one transparent electrode material selected from the group consisting of indium tin oxide and zinc oxide.

8. The method according to claim 2, wherein the transparent electrode film is made of at least one transparent electrode material selected from the group consisting of indium tin oxide and zinc oxide.

9. The method according to claim 2, wherein the transparent electrode film is formed on the substrate by at least one film-forming method selected from the group consisting of a vacuum evaporation method, a sputtering method, an ion-plating method, an ion-beam method, an atmospheric pressure chemical vapor deposition method, a low pressure chemical vapor deposition method, a plasma chemical vapor deposition method, a photochemical vapor deposition method, and a plasma polymerization method.

10. The method according to claim 3, wherein the transparent electrode film is formed on the substrate by at least one film-forming method selected from the group consisting of a vacuum evaporation method, a sputtering method, an ion-plating method, an ion-beam method, an atmospheric pressure chemical vapor deposition method, a low pressure chemical vapor deposition method, a plasma chemical vapor deposition method, a photochemical vapor deposition method, and a plasma polymerization method.

11. The manufacturing method according to claim 6, wherein the transparent electrode film is made of at least one transparent electrode material selected from the group consisting of indium tin oxide and zinc oxide.
